(19) United States
(12) Patent Application Publication
(10) Pub. No.: US 2008/0061812 A1
(43) Pub. Date: Mar. 13, 2008

(54) COMPONENT-ATTACH TEST VEHICLE

(75) Inventors: David K. McElfresh, San Diego, CA (US); Leoncio D. Lopez, Escondido, CA (US); Dan Vacar, San Diego, CA (US); Robert H. Melanson, San Diego, CA (US)

Correspondence Address: SUN MICROSYSTEMS, INC. c/o DORSEY & WHITNEY, LLP, 370 SEVENTEENTH ST., SUITE 4700, DENVER, CO, 80202, US

(73) Assignee: Sun Microsystems, Inc., Santa Clara, CA (US)

(21) Appl. No.: 11/531,657

(22) Filed: Sep. 13, 2006

(51) Int. Cl. G01R 31/26

(52) U.S. Cl. 324/765

(57) ABSTRACT

Apparatus, systems, and methods are provided for testing the integrity of electrical interconnections in electronic systems. Apparatus may be constructed by modifying a substrate designed for deployment in an end-use product by shorting together multiple contacts on one side of it. Such vehicles may be used to test the characteristics of interconnections between the vehicle and its support, the shorted contacts enabling testing of individual interconnects under both DC and AC conditions. A system for testing the interconnects may include the modified substrate, an input signal generator, and an output signal monitor.

### BACKGROUND

1. Field of the Invention

This invention relates to apparatus, methods, and systems used to test interconnections between components and assemblies to which they are attached.

2. Description of the Related Art

Specially constructed test packages are used to test the viability and reliability of component-attach methods, such as attaching integrated circuits (ICs), including application specific integrated circuits (ASICs) and central processing units (CPUs), to printed circuit boards (PCBs), for example by soldering with ball grid arrays (BGAs) or by using sockets. Sockets, in turn, may be soldered (using a pin or directly with a BGA, for example) or press-fitted to PCBs. These packages enable the electrical connections through the attach medium, solder or socket contacts, to be tested. Patterns of conductors, often “daisy chains,” on the opposite side of the packages provide electrical connections between interconnects, which are then probed to determine the quality of the connections through the attach medium.

The test packages currently used are often expensive, with some costing tens of thousands of dollars. They may also require a long lead time, that is, it may take several months for them to be delivered after an order is placed. Moreover, the test packages are built on substrates that are specific to the test vehicle and are not the substrates that will be used with the real ASICs or CPUs. Thus, they may not adequately reflect important mechanical aspects of real packages, such as the flatness, which may lead to erroneous conclusions about the reliability of the real packages they are designed to simulate. In addition, they can only test the direct current (DC) electrical characteristics of the attach interfaces and not the critical integrity of signals passed through those interfaces. Thus, signal integrity may not be assessed with these packages, again leading to possibly erroneous conclusions about the reliability of real packages with respect to their electrical performance. Neither are the current test packages able to distinguish the performance of individual interconnects—individual solder balls or socket contacts—so that the resulting reliability predictions have large calculation uncertainties. For example, in a current test package if a short chain connecting only a few individual interconnects fails, there is at least one interconnect failing, and possibly two or more. If a long chain fails, there may be as many as more than one hundred interconnects failing, and there is at least one. This lack of resolution leads to concomitantly poor resolution in the resulting reliability predictions.

### SUMMARY

Apparatus, systems, and methods are provided for evaluating the performance of electrical interconnections in electronic systems. An apparatus as described herein may be one of a batch of substrates destined for an end-use product and which is later modified by the addition of a conducting layer electrically connecting two or more contact pads on one side of the original substrate. In some implementations the conducting layer may be patterned, resulting in multiple islands of shorted contacts electrically isolated from each other. It may be desirable to attach other components, such as IC die, heat spreaders, and package lids, to the modified substrate to better simulate the conditions under which the interconnects will function when deployed in the field.

In some embodiments, apparatus may be constructed by modifying an original substrate designed for use in a functioning electronic device by shorting together multiple contacts on one side of it. In some cases the original substrate and the substrate to be used in the final packaged component may have substantially identical electrical or mechanical characteristics, or may be constructed of the same material, or may be fabricated by the same process, before modification as described herein. In some applications, these vehicles may be used to test the performance of interconnections between the substrate and an assembly to which it is attached, e.g., a PCB, as well as the integrity of signals sent through the interconnects to electrical paths that traverse the substrate. In some embodiments, the shorted contacts enable testing of individual connections to determine both DC and alternating current (AC), or frequency dependent, characteristics. A system for testing the interconnects may include the modified substrate, the interconnect to be tested, an input signal generator, and an output signal monitor.

The foregoing being a summary, it necessarily omits many aspects of the invention, which may be more fully appreciated with reference to the drawings and the following description. While illustrative examples are given for clarity of discussion, the invention is intended to be limited only by the appended claims.

### BRIEF DESCRIPTION OF THE DRAWINGS

The present invention may be better understood, and its numerous objects, features, and advantages made apparent to those skilled in the art by referencing the accompanying drawings.

FIG. 1 depicts the contact side of a substrate of an exemplary package for an integrated circuit (IC).

FIG. 2 depicts the die side of a substrate of an exemplary package for an IC.

FIG. 3 illustrates the die side of an exemplary test vehicle.

FIG. 4 depicts an exemplary test configuration using a test vehicle.

The use of the same reference symbols in different drawings indicates similar or substantially identical items.

### DESCRIPTION OF THE PREFERRED EMBODIMENTS

To distinguish between actual substrates designed to be used in a functioning electronic device, i.e. employable in a non-test environment, from those customized for use in merely testing portions of an electronic device, the former are referred to herein as “real,” “actual,” “standard,” “field-deployable,” “product-deployable,” or “fieldable,” while the latter are referred to as “test substrates,” “specially constructed substrates,” or “customized substrates.” Test packages containing real substrates need not be specially constructed, and the test packages described herein may be constructed using the actual substrates, heatspreaders, lid attach, and other materials and processes used to make the real packages. Because these substrates are those destined for real, or end-use, products, they are constructed of the same material and fabricated by the same process, and have virtually identical electrical and mechanical characteristics, including substrate-to-substrate variation. In some cases the product-deployable substrate may be further processed after fabrication to provide particular electrical or mechanical characteristics more specifically adapted to the test function, or it may be used as-is with only modifications as taught herein.

Specially constructed test packages are currently in use to evaluate component attach methods, such as attaching integrated circuits (ICs), including application specific integrated circuits (ASICs), or central processing units (CPUs) to printed circuit boards (PCBs) by using a variety of methods, including soldering with ball grid arrays (BGAs), through-hole type leaded devices, surface mount packages (SMT) of various designs, pin grid arrays (PGAs), and micro PGAs, and using sockets, for example. These test packages are often of a simpler construction than the real packages that will be used in the field. They therefore may not adequately represent some of the characteristics critical to the performance of the attach methods they are designed to test. For example, test packages are often much flatter than the real packages, and test packages do not show the package-to-package variation of real packages, such as geometric variation in shape, height, etc., and variations in solder joints, especially residual strain. The performance of sockets is extremely sensitive to package flatness. Greater flatness of the test packages also leads to less variation in solder joints across a package which leads to better performance in cyclic stressing than for real packages. In addition, the greater flatness leads to better overall performance, less sensitivity to variations in the required hardware, and better reliability.

One of the main functions of interconnects is to cleanly pass signals back and forth between the semiconductor device and the PCB. The tests to evaluate component attach methods are generally performed by supplying a signal to an input interconnect and reading the resultant signal at an output interconnect. The current test packages using specially constructed substrates cannot assess signal integrity performance because they do not contain the actual signal paths of the real devices and because they pass signals through at least two interconnects, and up to more than one hundred. Use of these test packages and measurements made with them may result in failure to anticipate problems or specify proper tolerances, and in estimation of much better quality, yield, and reliability than is achieved in the real end-use product. In some embodiments of the invention disclosed herein, by employing standard components rather than components customized for use in testing, test packages may be obtained more quickly, i.e. with less lead time, and for lower cost than the test packages used today. In some embodiments packages that are virtually indistinguishable from real packages but for the modifications taught herein may be used to accurately evaluate performance, quality, yields, and reliability, and so to properly specify most or all of the critical tolerances.

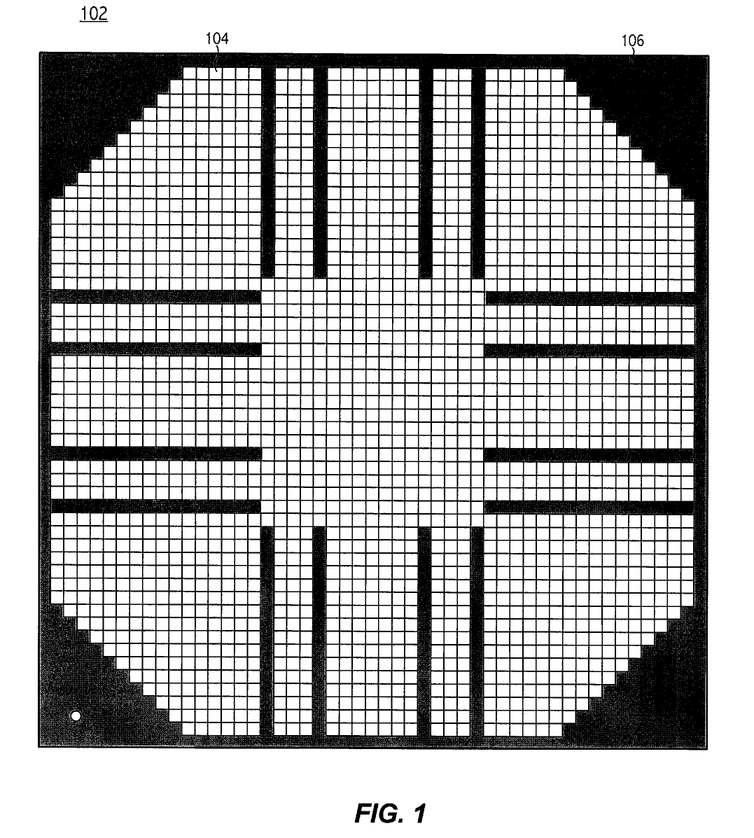

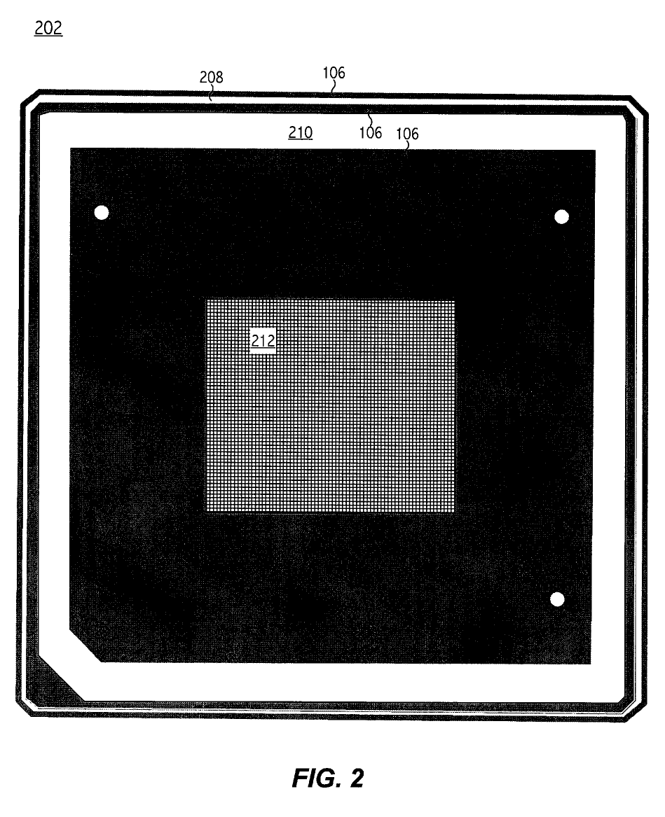

FIGS. 1 and 2 depict contact 102 and die 202 sides, respectively, of a substrate of an exemplary package for an integrated circuit (IC) to be used in a product. (Regardless of whether the product consists of the IC alone, or the IC in combination with other ICs, PCBs, or other assemblies comprising a complete end-use product or a portion of one, the substrate is still deployed in any of these end-use products.) On the contact side 102, metal leads or electrical contact areas (pads) 104 made of a conductor, often a metal or metallic compound, are patterned on the substrate material 106, which may be ceramic, plastic, glass, organic, or a composite, depending on the particular application. On the die side 202 of the substrate, conductor material is patterned on the substrate material 106 as required to form conductive areas for the application, illustrated in this simplified configuration as an outermost ring 208, a wide ring 210, and die contact pads 212. Other implementations may employ wire bonds either within the package itself or between the package and the IC. Electrical paths traverse the substrate material 106 to connect the pads 104 on the contact side 102 of the substrate to respective contact areas on the die side 202 of the substrate. In actual use, an IC (the die or chip) may be bonded to the die contact pads 212, and electrical connections made from the die contact pads 212 to any additional conductors as may be required by the particular application.

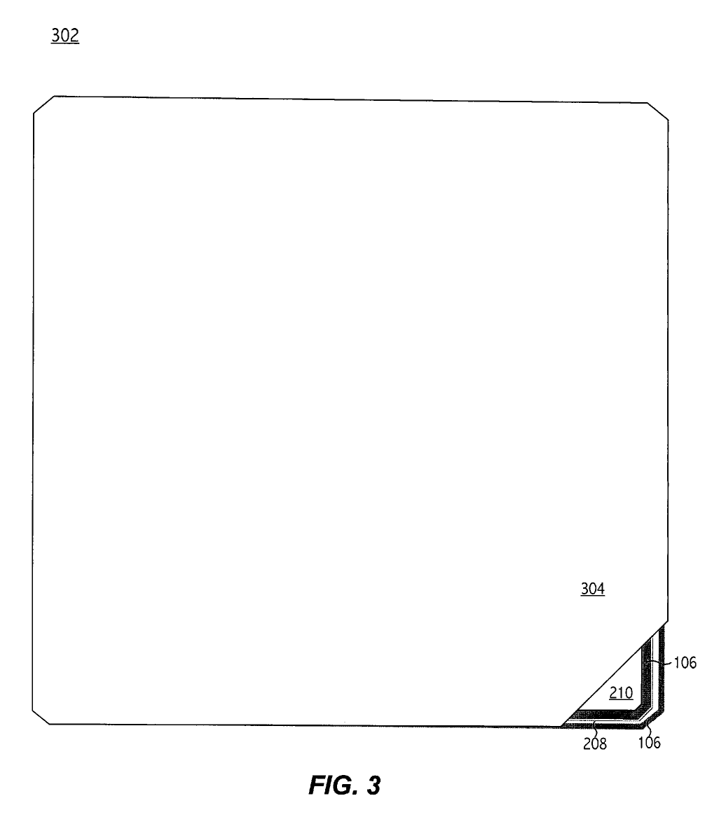

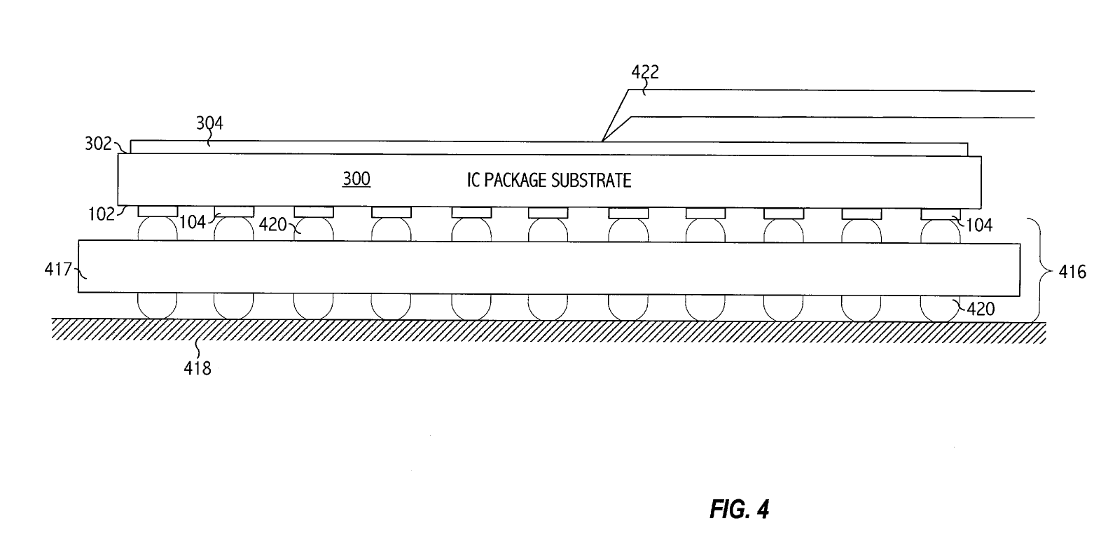

FIG. 3 illustrates the die side 302 of an exemplary test vehicle constructed using the real substrate depicted in FIG. 2. The product-deployable substrate of FIG. 2 is modified by electrically shorting together the contact pads (the conductive areas 208, 210, and 212 of FIG. 2) on the die side 202 of the substrate by a layer of conductor 304, to form a (nearly) equipotential plane on the die side 302 of the modified substrate 300 (see FIG. 4). The contacts on the die side of the original package may be connected in many ways including depositing a metal or other conductive material by sputtering or evaporation, by melting and freezing a conductive material such as a solder, by depositing a conductive material such as a die attach or conductive “paint,” or by screen printing a conductive paste and then “firing” the substrate and paste as is done in the construction of multilayer ceramic packages, among other methods. Most of these methods can be post-processed with lithographic techniques to define patterns of connections, such as a set of electrically isolated conductive islands each shorting two or more die contacts together, or other features as desired. For example, the standard customized test packages use a daisy chain pattern. Other methods of selectively severing electrical connections between contacts may include laser ablation and scribing. As few as two or three contacts, or as many as tens, hundreds, or thousands, may be connected by a conducting layer or conductive islands. In some cases the conductive layer 304 may be provided by a conducting heat spreader. The characteristics of the electrical paths passing through the substrate and of the interconnects are not altered by the formation of the equipotential plane.

After the conductive layer 304 is formed, additional items, including the semiconductor device, heatspreader, and/or lid, may be added to make a package that is nearly identical to a real product-deployable package. In some cases the package may be fully assembled on the modified substrate, with all components attached as in the real product. This package will have been exposed to the same assembly processes as real packages, and its mechanical parameters, thermal response, and internal electrical paths and characteristics will be substantially identical (accounting for normal package-to-package variation) to those of real packages.

FIG. 4 depicts an exemplary test configuration using the modified substrate 300. A socket 416, depicted as a land grid array (LGA), is mounted on a PCB 418, which may be a test board or a board intended for use in the final product. Conductors 420, depicted here as pins, running through the plate 417 of the socket 416 electrically connect the modified substrate 300 and the PCB 418 by making contact with contact pads, or “lands,” 104 on the contact side 102 of the modified substrate 300 at one end of the conductors 420 and with conductive areas on the PCB 418 at the other end. Depicted here as extending past both edges of the plate 417, conductors 420 are generally compressed during use below the lip (not visible in the edge-on view of FIG. 4) of the plate 417. Conductors 420 are made of a conductive material which may be a pillar or column of a conductive polymer, a spring metal, wires of various types, or randomly wound wires, for example.

To test an interconnection, a signal is supplied to one of the contacts 104 on the contact side 102 of the substrate 300 through one of the conductors 420, and the resulting output signal is detected by a probe 422 in contact with the conductive layer 304 on the opposite side 302 of the substrate. (Of course, the input signal may be supplied at the die side 302 of the substrate 300 and the output read at the contact side 102.) The probe 422 may be connected to whatever monitoring instrument is appropriate for the property to be measured, such as an oscilloscope, a voltage meter, a strain meter, or a recording device or printer. By detecting the output signal at the side opposite the substrate from the input signal, rather than at a second conductor 420, it is possible to test a single electrical path from the input contact through the substrate and so test the characteristics of an individual interconnect. When testing individual interconnects using a socket, the input signal may be supplied, or the output signal measured at, the socket itself rather than going through the support structure (a PCB for example) when it is desirable to determine characteristics of the interconnection.

Solder interconnections may also be tested as described with reference to FIG. 4. In the case of solder interconnects, a quantity of solder is melted and solidified between the contact pads 104 and corresponding conductive areas on the support, e.g., a PCB, forming solder balls or columns. When using either solder or sockets, signals may be supplied or measured at the PCB if desired.

Depending on the signals supplied, many characteristics of the interconnects can be determined. Some of the parameters measured may include distortion of an input sine wave, impedance as a function of the frequency of the input signal, bit error rate, retry rate, signal-to-noise ratio, and eye diagram opening shape and size. The physical integrity of the connection may be detected by applying a DC signal. Mechanical properties of the interconnects, such as deformation of the interconnects or the package or residual strain in solder joints, may be monitored separately from the electrical characteristics, or may be monitored simultaneously. The modification of the substrate does not affect the results of routine tests such as time-domain reflectometry (TDR), which may be employed in addition to or instead of other evaluation methods so far described. Neither does the substrate modification affect accelerated aging methods such as thermal cycling or repeatedly applying mechanical stresses.

For the case where many or all of the contacts on the die side 302 of the substrate 300 are connected together on an equipotential plane, access is needed to that plane. When the conductive layer 304 is exposed as depicted in FIG. 4, this is straightforward. Direct contact between the probe 422 and the equipotential plane is not required to test the interconnections, however. If additional package components are added, contact with the conductive layer 304 can be accomplished in many ways, including using a conductive adhesive or solder to attach a metal heatspreader to the equipotential plane, using a conductive material such as solder to connect the edge of a metal heatspreader to the equipotential plane, or creating the equipotential plane so that it extends to the edge of the substrate where it can be contacted regardless of the type of heatspreader. In cases where a heatsink or other hardware is stacked on top of the heatspreader, the equipotential plane can be accessed by contacting the equipotential plane with the heatsink. In the cases where the heatspreader is not electrically conductive and there is a heatsink or other hardware stacked on top of the heatspreader, the equipotential plane can be accessed through the heatsink by connecting it to the extension of the equipotential plane on the substrate by soldering a wire or providing other conductive media between them.

When some or all of the contacts on the die side are connected together, the electrical performance of individual contacts can be monitored by measuring from the equipotential plane through the contact and to a connection on the PCB. This approach of monitoring individual contacts and its many advantages, including the resulting more accurate reliability predictions, are described in co-pending U.S. patent application Ser. No. 11/345,557, filed Jan. 31, 2006, entitled “Reliability Prediction for Complex Components,” and naming Leoncio D. Lopez, David K. McElfresh, and Dan Vacar as inventors, which application is hereby incorporated by reference herein in its entirety.

Since actual substrates are often available early in the development cycle of an integrated circuit, use of real substrates modified as taught herein may allow evaluations of the performance and reliability of component-attach methods to be done earlier in the development process, and at lower cost. Such an approach may also produce results that are more accurate than does the existing approach, as described elsewhere.

Although the foregoing description has used the example of a substrate, such as an IC die carrier, designed to attach an IC to a PCB, other embodiments are possible. For example, testing interconnections between a chip carrier or PCB and a bare die may be accomplished by similarly shorting electrical paths within the die to an equipotential plane. In the case of a die, the equipotential plane may be formed by removing the back side of the wafer down to a layer of common terminus, and then depositing a metal coating, for example. Alternatively, a test die may be constructed by forming a ground plane during fabrication, with electrical connections between the ground plane and the bonding pads on the chip's surface built in. In yet another embodiment, the method described herein may be used to test interconnections between PCBs, between PCBs and universal panel adapters, or between any pair of components used in the electronics industry.

For the purposes of clarity of description, the test vehicle is often referred to as “substantially identical” in some aspect to real substrates. Persons of ordinary skill in the art will realize that substrates and packages, and in fact, most manufactured items, exhibit minor variations in electrical, thermal, and mechanical properties both between batches and within a batch. These minor variations fall within certain tolerances for substrates employed in actual end-use products; large deviations of these properties from pre-defined target values cause the piece to be rejected as unfit for its intended purpose. The test vehicles described herein are substantially identical to product-deployed substrates when the characteristics of at least one type of property falls within the acceptable limits for deployed substrates. For example, if only the mechanical properties of a bond are to be tested, only the mechanical properties need be the same as for a product-deployed for the tests to enjoy the accuracy and predictive ability provided by using a test vehicle made from deployable substrates modified as described herein. Alternatively, when thermal, mechanical, and electrical properties are to be evaluated in concurrent or sequential tests, as when signal integrity is evaluated before and after thermomechanical stress, multiple properties of the test vehicle may fall within the respective tolerances for substrates deployed in end-use products.

While the invention has been described with reference to various realizations, it will be understood that these realizations are illustrative and that the scope of the invention is not limited to them. Many variations, modifications, additions, and improvements are possible. As used herein, plural instances may be provided for components described as a single instance, and vice versa. These and other variations, modifications, additions, and improvements may fall within the scope of the invention as defined in the claims that follow.

What is claimed is:

1. A test vehicle comprising:
a product-deployable substrate,
the substrate having first and second sides and a plurality of electrical paths passing therethrough, the electrical paths electrically connecting electrical contact areas defined on the first side to corresponding electrical contact areas defined on the second side; and
a conductive layer electrically connecting a first group of at least two of the electrical contact areas on the first side of the substrate.

2. The test vehicle of claim 1, wherein:
the electrical paths through the product-deployable substrate are substantially identical to electrical paths through a substrate deployed in an end-use product.

3. The test vehicle of claim 1, wherein:
the product-deployable substrate and a substrate deployed in an end-use product are constructed of substantially identical materials.

4. The test vehicle of claim 1, wherein:
the product-deployable substrate and a substrate deployed in an end-use product are fabricated by substantially identical processes.

5. The test vehicle of claim 1, wherein the first group comprises at least three of the electrical contact areas on the first side of the substrate.

6. The test vehicle of claim 5, wherein the first group comprises all of the electrical contact areas on the first side of the substrate.

7. The test vehicle of claim 1, wherein the conductive layer is patterned.

8. The test vehicle of claim 7, wherein:
the patterned conductive layer comprises a plurality of conductive islands,
a first island electrically connecting the first group of electrical contact areas; and
a second island electrically connecting a second group of at least two of the remaining electrical contact areas on the first side of the substrate, the first island electrically isolated from the second island.

9. The test vehicle of claim 1, wherein the substrate comprises an integrated circuit package substrate.

10. A method of making a test vehicle, the method comprising:
modifying a product-deployable substrate by forming electrical connections between a plurality of electrical contacts on a first side of the substrate; and
providing the modified substrate as a test vehicle.

11. The method of claim 10, wherein forming the electrical connections comprises forming a conductive layer electrically connecting the electrical contacts.

12. The method of claim 11, further comprising:
selectively severing electrical connections between the electrical contacts.

13. The method of claim 12, wherein the selective severing comprises lithographically patterning the conductive layer.

14. A method of testing electrical interconnects, the method comprising:
supplying an input signal through an interconnect to a first electrical contact area on a first side of a product-deployable substrate,
the first electrical contact area electrically connected to a second electrical contact area on a second side of the substrate; and
monitoring an output signal responsive to the input signal at an equipotential plane,
the equipotential plane formed by electrically connecting the second electrical contact area and at least one other electrical contact area on the second side of the substrate by a conducting layer.

15. The method of claim 14, wherein supplying the input signal comprises:
making electrical contact between the first electrical contact area and a printed circuit board; and
supplying the input signal to the printed circuit board.

16. The method of claim 15, wherein making electrical contact comprises:
soldering the first electrical contact area to a respective conductive area on the printed circuit board.

17. The method of claim 15, wherein making electrical contact comprises:
electrically connecting the first electrical contact area to a conductor of a socket; and
electrically connecting the socket to the printed circuit board.

18. The method of claim 14, further comprising:
attaching to the substrate one or more of an integrated circuit die and a lid.

19. The method of claim 14, further comprising:
attaching a heat spreader to the substrate.

20. The method of claim 19, wherein the monitoring comprises:
making electrical contact between the equipotential plane and the heat spreader; and
measuring the output signal on the heat spreader.

21. A system for testing electrical interconnections comprising:
a modified substrate, the modified substrate comprising a product-deployable substrate and a conductive layer covering a portion of a first side of the substrate, the conductive layer electrically connecting a plurality of electrical paths traversing the substrate;
means for making electrical contact to a first of the electrical paths at a second side of the substrate;
means for supplying an input signal via an interconnect to the first electrical path at one of the first and second sides of the substrate; and
means for measuring an output signal responsive to the input signal at the side of the substrate not supplied the input signal.
